(19) United States
(12) Patent Application Publication
(10) Pub. No.: US 2016/0161637 A1
(43) Pub. Date: Jun. 9, 2016

(54) TRANSPARENT CONDUCTING ELECTRODE USING A METAMATERIAL HIGH PASS FILTER

(71) Applicant: National Tsing Hua University, Hsinchu (TW)

(72) Inventors: Ta-Jen YEN, Hsinchu (TW); Ting-Tso YEH, Hsinchu (TW); Dong-Sheng SU, Hsinchu (TW)

(21) Appl. No.: 14/794,076

(22) Filed: Jul. 8, 2015

(30) Foreign Application Priority Data
Dec. 5, 2014 (TW) 103142352

(51) Int. Cl. G02B 1/00; G02B 5/20; H05K 1/09; H05K 1/03; H05K 1/02

(52) U.S. Cl. CPC G02B 1/002; H05K 1/0326; H05K 1/0274; H05K 1/0296; H05K 1/09; G02B 5/20; H05K 2201/0108; H05K 2201/0145

(57) ABSTRACT

A transparent conducting electrode using a metamaterial high pass filter includes a substrate and a metal layer. The metal layer is disposed on a surface of the substrate and has a plurality of periodic patterns, wherein the plurality of periodic patterns are interconnected to form a metamaterial structure with subwavelength meshes, and a size of open area of the periodic pattern is smaller than the average wavelength of visible light. The abovementioned transparent conducting electrode using the metamaterial high pass filter has advantages of higher transmittance, conductivity and flexibility and lower process temperature.

### BACKGROUND OF THE INVENTION

1. Field of the Invention

The present invention relates to a conducting electrode, and particularly to a transparent conducting electrode using a metamaterial high pass filter.

2. Description of the Prior Art

At present, many electronic applications require the use of transparent conducting electrode, such as electrodes of solar cells, driving electrodes of organic light-emitting diodes (OLED), and driving electrodes of displays, etc. A conventional transparent conducting electrode has used metal oxides, such as Indium Tin Oxide (ITO), Indium Gallium Oxide (IGO) or Indium Gallium Oxide Zinc (IGZO), etc. However, for example, a process for forming indium tin oxide on a substrate is needed to form a crystal film under a high temperature (e.g., above 200 degrees Celsius). As a result, the substrate must have considerable heat resistance. Traditionally, in most cases, the indium tin oxide is formed on a glass substrate, and the indium tin oxide has less mechanical strength so that the electronic element is not flexible. In addition, a light transmittance of the indium tin oxide is about 80%, and a resistance of the indium tin oxide is about 50 ohm/area, which still can be improved.

To sum up the foregoing descriptions, providing a transparent conducting electrode, which can be formed on a substrate having lower heat resistance, is the most important goal for now.

### SUMMARY OF THE INVENTION

The present invention is directed to providing a transparent conducting electrode using a metamaterial high pass filter, which is provided with a metamaterial structure with meshes formed by a metal layer. By adjusting parameters of the metamaterial structure, the metal layer may have a light transmittance and may be used as a transparent conducting electrode.

A transparent conducting electrode using a metamaterial high pass filter of one embodiment of the present invention comprises a substrate and a metal layer. The metal layer is disposed on a surface of the substrate and has a plurality of periodic patterns, wherein the plurality of periodic patterns are connected with each other to form a metamaterial structure with meshes, and a size of the meshes of the periodic patterns is smaller than the average wavelength of visible light.

The objectives, subject matters and properties of the present invention and the effects achieved by the present invention will become apparent from the following descriptions of the embodiments taken in conjunction with the accompanying drawings.

### BRIEF DESCRIPTION OF THE DRAWINGS

FIG. 1 is a schematic view, showing a transparent conducting electrode using a metamaterial high pass filter of one embodiment of the present invention.

FIG. 2 is a sectional view, showing a sectional structure of a transparent conducting electrode using a metamaterial high pass filter of one embodiment of the present invention, taken along the line A-A of FIG. 1.

FIG. 3 is a schematic view, showing a transparent conducting electrode using a metamaterial high pass filter of another embodiment of the present invention.

FIG. 4 is a schematic view, showing a transparent conducting electrode using a metamaterial high pass filter of still another embodiment of the present invention.

FIG. 5 is a curve diagram, showing a light transmittance in a wavelength range of the visible light of a transparent conducting electrode using a metamaterial high pass filter of one embodiment of the present invention.

### DESCRIPTION OF THE PREFERRED EMBODIMENT

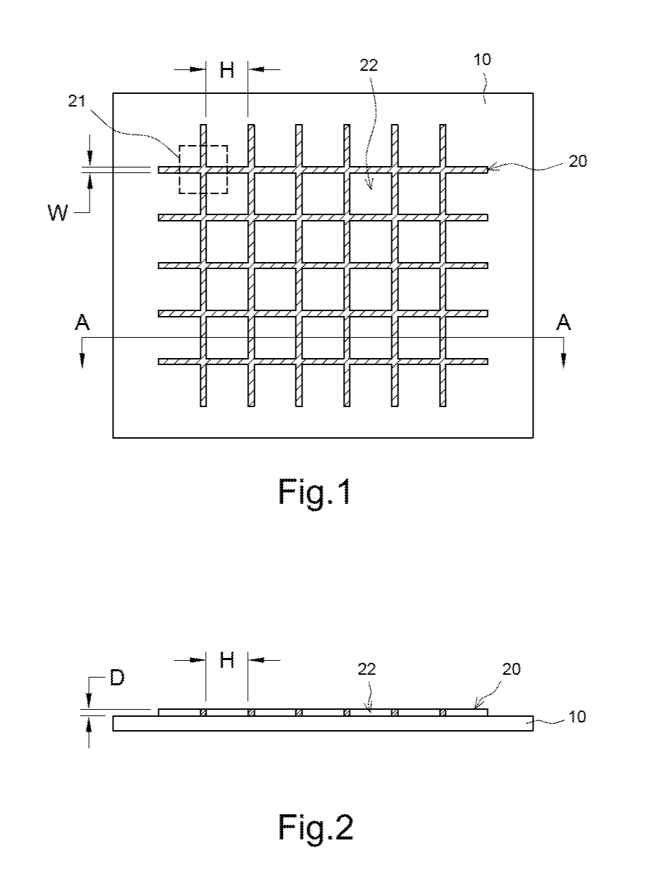

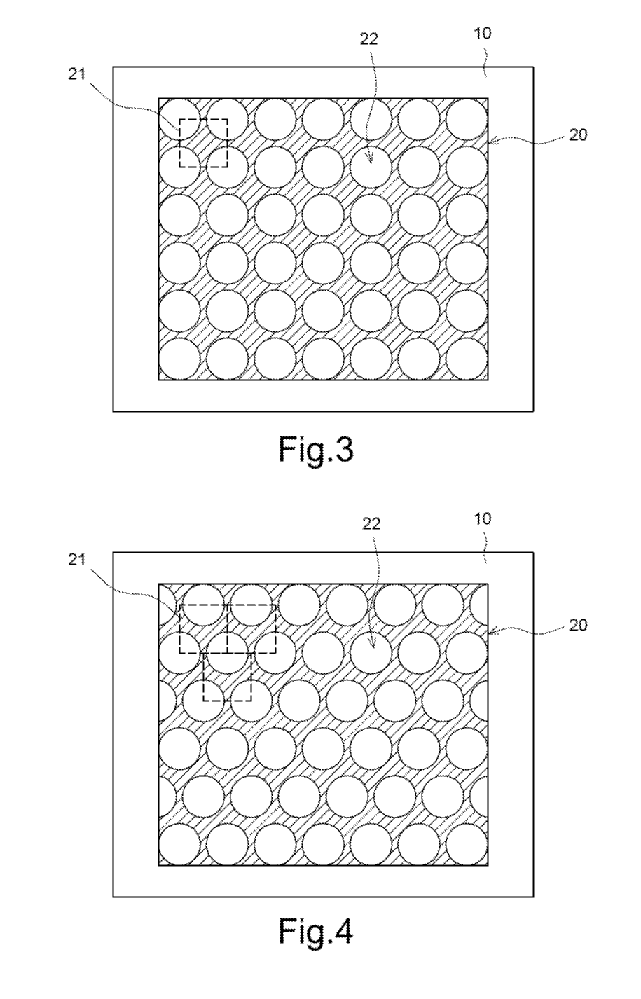

Referring to FIG. 1 and FIG. 2, a transparent conducting electrode using a metamaterial high pass filter of one embodiment of the present invention comprises a substrate 10 and a metal layer 20. In one embodiment, the substrate 10 may be transparent high polymer or glass. For example, the substrate 10 may be polyethylene terephthalate (PET). The metal layer 20 is disposed on a surface of the substrate 10 and has a plurality of periodic patterns 21. Moreover, the plurality of periodic patterns 21 are connected with each other to form a metamaterial structure with meshes 22. The shape of the meshes 22 of the periodic patterns 21 may be square (as shown in FIG. 1), circular (as shown in FIG. 3) or regular polygon (e.g., regular triangle or regular hexagon). In addition, the meshes 22 of the periodic patterns 21 may be arranged in an array (as shown in FIG. 1 and FIG. 3) or in an interlaced manner (as shown in FIG. 4). In one embodiment, the metal layer 20 may be gold, silver, copper or aluminum. The metal layer 20 may be formed on a surface of the substrate 10 under a lower process temperature with nano-imprint and e-gun evaporation. As a result, the substrate 10 may adopt a material having lower heat resistance, e.g., high polymer such as PET.

Different metals have different plasma frequencies. By adjusting the periodic structure of the metamaterial, i.e., the periodic patterns 21 of the metal layer 20, a natural plasma frequency of a metal (typically in the frequency range of ultraviolet) may be lowered, such that a light of a particular wavelength having a frequency higher than the lowered plasma frequency may transmit through the metal layer 20 which originally may not be transmitted through. For example, when the size H of the meshes of the periodic patterns 21 of the metal layer 20 is smaller than the average wavelength of the visible light, the visible light can transmit through the metal layer 20 regardless what material properties of the metal layer 20 may be. In one embodiment, the size H of the meshes of the periodic patterns 21 is smaller than 580 nm. According to such structure, the visible light having a wavelength smaller than 780 nm can transmit through the metal layer 20 and have higher transmittance. Because the metal layer 20 has a high conductivity in nature, the metal layer 20 having a metamaterial structure may be used as a transparent conducting electrode.

A cycle of the periodic patterns 21 is a main parameter for adjusting the light transmittance of the metal layer 20, which is not a limitation. A line width W of the periodic patterns 21 and a thickness D of the metal layer 20 may also be used to adjust the light transmittance of the metal layer 20. For example, when the cycle is the same, increasing the line width W (i.e., decreasing the size H of the meshes) may lower the light transmittance. When the cycle and the line width W are the same, increasing the thickness D of the metal layer 20 may lower the light transmittance as well. In one embodiment, a ratio of the size H of the meshes of the periodic patterns 21 to the line width W of the periodic patterns 21 is equal to or more than 8. In one embodiment, the thickness D of the metal layer 20 is less than 150 nm.

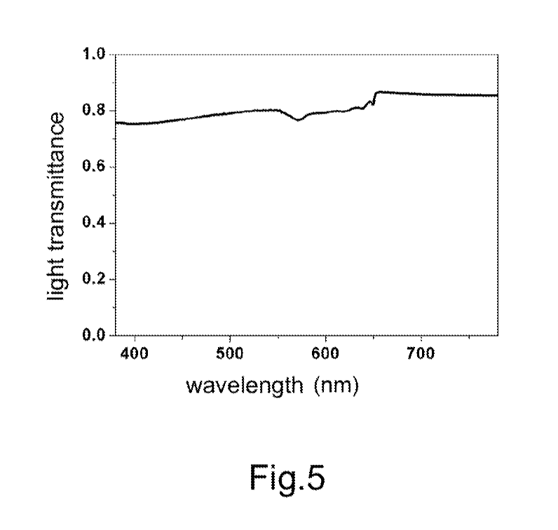

Refer to FIG. 5, illustrating a light transmittance of a transparent conducting electrode using a metamaterial high pass filter of one embodiment of the present invention in a wavelength of the visible light. The substrate 10 of the present embodiment is PET. The metal layer 20 is made of aluminum. The periodic patterns 21 are shown as FIG. 1. The size H of the meshes of the periodic patterns 21 is 580 nm. The line width W is 72.5 nm. The thickness of the metal layer 20 is 50 nm. As seen from FIG. 5, the transparent conducting electrode using a metamaterial high pass filter of the present invention has an average light transmittance of 80.76% in a wavelength range of the visible light (from 380 nm to 780 nm), which is better than the light transmittance of the conventional ITO electrode (80%). It is noted that the transparent conducting electrode using a metamaterial high pass filter of the present invention is made of a metal, so that its resistance is about 5 ohm/area, which is also superior to the resistance of the conventional ITO electrode (50 ohm/area). Moreover, because the PET has flexibility and the metal layer 20 has ductility, the transparent conducting electrode using a metamaterial high pass filter of the present invention may be applied to a flexible electronic element.

To sum up the foregoing descriptions, the transparent conducting electrode using a metamaterial high pass filter of the present invention is provided with a metamaterial structure with meshes formed with a metal layer. By adjusting parameters of the metamaterial structure, the metal layer may have a light transmittance and may be used as a transparent conducting electrode. Compared with the conventional transparent conducting electrode, e.g., the ITO electrode, the transparent conducting electrode of the present invention has advantages of higher light transmittance, higher conductivity, lower process temperature, more types of substrates which can be chosen, flexibility, avoiding the moire effect, and low cost. Furthermore, low light out-coupling efficiency caused by trapping a great amount of light between the ITO layer and the holes transport material layer in the conventional OLED can be improved by replacing the ITO layer with the transparent conducting electrode of the present invention. Consequently, an OLED product with higher transmittance, lower resistivity, better out-coupling efficiency and easier to be fabricated can be achieved.

The above-mentioned embodiments are only descriptions of the subject matters and properties of the present invention, which objective is to enable those skilled in the art to understand the content of the present invention and practice the present invention accordingly, and it can never limit the patent scope of the present invention. All equivalent variations or modifications which are made according to the spirit disclosed by the present invention should be covered within the patent scope of the present invention.

What is claimed is:

1. A transparent conducting electrode using a metamaterial high pass filter, comprising:
a substrate; and
a metal layer disposed on a surface of the substrate and having a plurality of periodic patterns, wherein the plurality of periodic patterns are interconnected to form a metamaterial structure with meshes, and a size of the meshes of the periodic patterns is smaller than the average wavelength of visible light.

2. The transparent conducting electrode using a metamaterial high pass filter according to claim 1, wherein the size of the meshes of the periodic patterns is smaller than 580 nm.

3. The transparent conducting electrode using a metamaterial high pass filter according to claim 1, wherein a ratio of the size of the meshes of the periodic patterns to a line width of the periodic patterns is equal to or more than 8.

4. The transparent conducting electrode using a metamaterial high pass filter according to claim 1, wherein a shape of the meshes of the periodic patterns is square, circular or regular polygonal.

5. The transparent conducting electrode using a metamaterial high pass filter according to claim 1, wherein the meshes of the periodic patterns are arranged in an array.

6. The transparent conducting electrode using a metamaterial high pass filter according to claim 1, wherein the meshes of the periodic patterns are arranged in an interlaced manner.

7. The transparent conducting electrode using a metamaterial high pass filter according to claim 1, wherein the metal layer comprises gold, silver, copper or aluminum.

8. The transparent conducting electrode using a metamaterial high pass filter according to claim 1, wherein a thickness of the metal layer is less than 150 nm.

9. The transparent conducting electrode using a metamaterial high pass filter according to claim 1, wherein the substrate comprises a transparent high polymer or glass.

10. The transparent conducting electrode using a metamaterial high pass filter according to claim 1, wherein the substrate comprises polyethylene terephthalate (PET).
